(19) United States
(12) Patent Application Publication
(10) Pub. No.: US 2007/0230118 A1
(43) Pub. Date: Oct. 4, 2007

(54) Circuit board including components aligned with a predominant air flow path through a chassis

(76) Inventors: Javier Leija, Chandler, AZ (US); Mark D. Summers, Phoenix, AZ (US); William Handley, Chandler, AZ (US); Edoardo Campini, Mesa, AZ (US)

Correspondence Address: Grossman, Tucker, Perreault & Pfleger, PLLC;PortfolioIP, P.O. Box 52050, Minneapolis, MN, 55402, US

(21) Appl. No.: 11/394,725

(22) Filed: Mar. 31, 2006

(51) Int. Cl. H05K 7/20

(52) U.S. Cl. 361/690

(57) ABSTRACT

One or more components on one or more circuit boards in a chassis may be configured and/or oriented such that the component(s) are aligned with a diagonal predominant air flow path through the chassis. In one embodiment, components may be mounted on a circuit board with a skewed orientation that aligns the components with the predominant air flow path. In another embodiment, one or more heat sinks may include angled fins that are aligned with the predominant air flow path. Of course, many alternatives, variations, and modifications are possible without departing from this embodiment.

### FIELD

The present disclosure relates to circuit boards including components configured and/or oriented on the circuit boards to be aligned with a predominant air flow path through a chassis including the circuit boards.

### BACKGROUND

Increases in processor speeds and circuit board densities have resulted in an increase in the heat generated by computer systems and other electronics systems. In an Advanced Telecommunications Computing Architecture (ATCA) system, for example, dense blades (i.e., circuit boards) populated with silicon chips, such as single board computer (SBC) blades with microprocessors, may dissipate up to 200 W of power per blade, which may result in a total dissipation of 2800 W in a 14 slot chassis. The heat generated by such power dissipation rate may cause semiconductor performance degradation, mean time between failure (MTBF) reduction and even catastrophic damage. Thus, the performance and reliability of such electronic systems may be dependent on the ability to provide adequate cooling in the chassis.

In computer systems, such as ATCA systems, heat generated by various components of the system may be removed using forced convection. In a forced convection cooling system, a fan may be used to circulate air within a housing or chassis of the computer system. In many systems, the fan may be used to force the intake of air from the exterior of the computer system, pass the air through the housing or chassis, and exhaust heated air from the housing or chassis. The airflow velocity may be increased to meet the increasing cooling constraints brought on by increases in heat dissipation caused by higher performance components.

In some systems, the components on the circuit boards (e.g., the components on the blades in an ATCA chassis) may be oriented in a way that impedes the air flow through the chassis, resulting in higher backpressure, turbulence and decreased air flow. Where the predominant air flow path is diagonal through a chassis (e.g., from the front bottom region to the top rear region), for example, components that are orthogonally positioned on a circuit board (e.g., with edges perpendicular to the circuit board edges) may impede the air flow. In particular, higher profile components directly in the flow path, such as heat sinks used with heat generating components, may be more likely to impinge upon the air flow through the chassis. The heat sinks are often positioned on top of the heat generating components (e.g., high power, high performance processors) and oriented orthogonally relative to the circuit board (similar to the component) such that the fins of the heat sink extend into and impinge upon the flow path. As a result of the decreased air flow caused by the components on the circuit boards in the chassis, cooling efficiency may be reduced. The turbulence may also cause increased noise levels as a result of increased airflow velocity to meet the cooling requirements.

### BRIEF DESCRIPTION OF DRAWINGS

Features and advantages of the claimed subject matter will be apparent from the following detailed description of embodiments consistent therewith, which description should be considered with reference to the accompanying drawings, wherein:

FIG. 1 is a side cross-sectional view of a computer system chassis illustrating airflow through the chassis;

FIG. 2A is a side cross-sectional view of a computer system chassis containing one or more circuit boards including skewed components, consistent with one embodiment of the present disclosure;

FIG. 2B is a side cross-sectional view of the chassis shown in FIG. 2A illustrating a predominant airflow path aligned with the skewed components;

FIG. 3A is a side cross-sectional view of a computer system chassis containing one or more circuit boards including heat sinks with angled fins, consistent with another embodiment of the present disclosure;

FIG. 3B is a side cross-sectional view of the chassis shown in FIG. 3A illustrating a predominant airflow path aligned with the angled fins of the heat sinks; and

FIG. 4 is a perspective view of a system including a cabinet and a plurality of chassis, consistent with a further embodiment of the present disclosure.

Although the following Detailed Description will proceed with reference being made to illustrative embodiments, many alternatives, modifications, and variations thereof will be apparent to those skilled in the art. Accordingly, it is intended that the claimed subject matter be viewed broadly.

### DETAILED DESCRIPTION

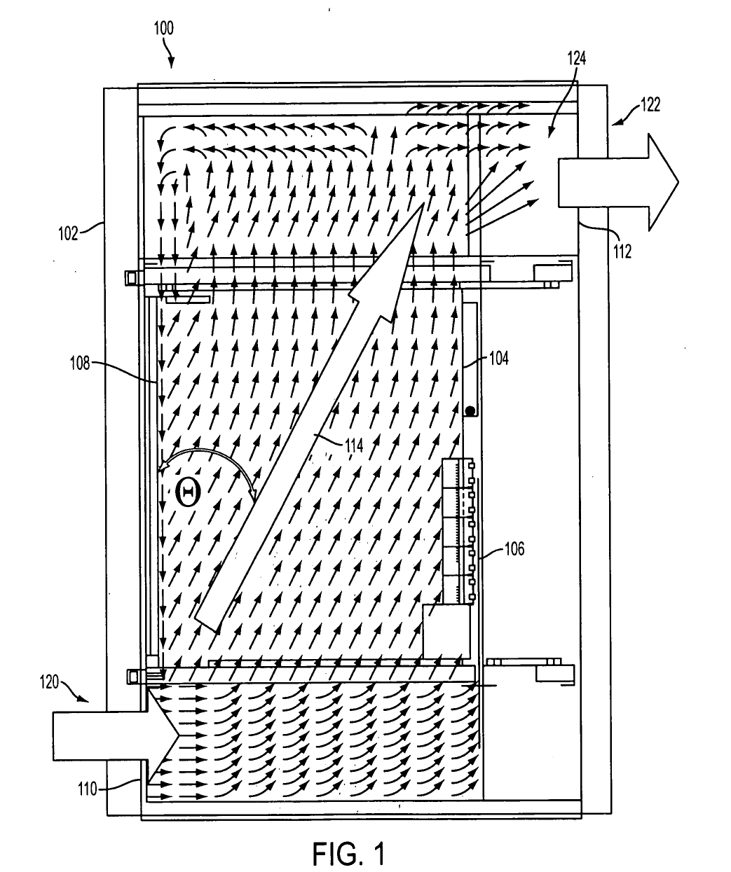

Referring to FIG. 1, a computer or electronic system 100 may include a chassis 102 and one or more circuit boards 104, for example, coupled to a backplane 106 in the chassis 102. The circuit board(s) 104 may include one or more heat generating components (not shown in FIG. 1) such as, for example, processors, co-processors, chipsets, graphics chips, and memory modules, which may be cooled by forced convection as air flows through the chassis 102 and across the components. As will be described in greater detail below, one or more of the components may be configured and/or oriented on the circuit board(s) 104 such that the components are aligned with a predominant air flow path through the chassis 102, thereby reducing impedance to air flow and improving cooling.

The chassis 102 may include an air inlet 110 allowing air to enter the chassis 102 and an air outlet 112 allowing air to exit the chassis 102 such that a predominant air flow path 114 extends along a path of least resistance from the inlet 110 toward the outlet 112. Those skilled in the art will recognize that air flow is complex and a portion of air may flow along a different path from the predominant air flow path 114. In one embodiment, the inlet 110 and the outlet 112 may be cater-cornered in the chassis 102 such that the predominant air flow path 114 is diagonally through the chassis 102. For example, the inlet 110 may be located in a bottom front region 120 of the chassis 102 and the outlet 112 may be located in a top rear region 122 of the chassis 102. In this exemplary embodiment, the predominant air flow path 114 may be at an angle Θ in the range of about 45°±20° relative to one side of the chassis 102 (or an edge 108 of the circuit board 104 orthogonally mounted in the chassis 102). One or more fans 124 located in the top rear region 122 of the chassis 102 may draw the air through the chassis 102, causing the air to flow.

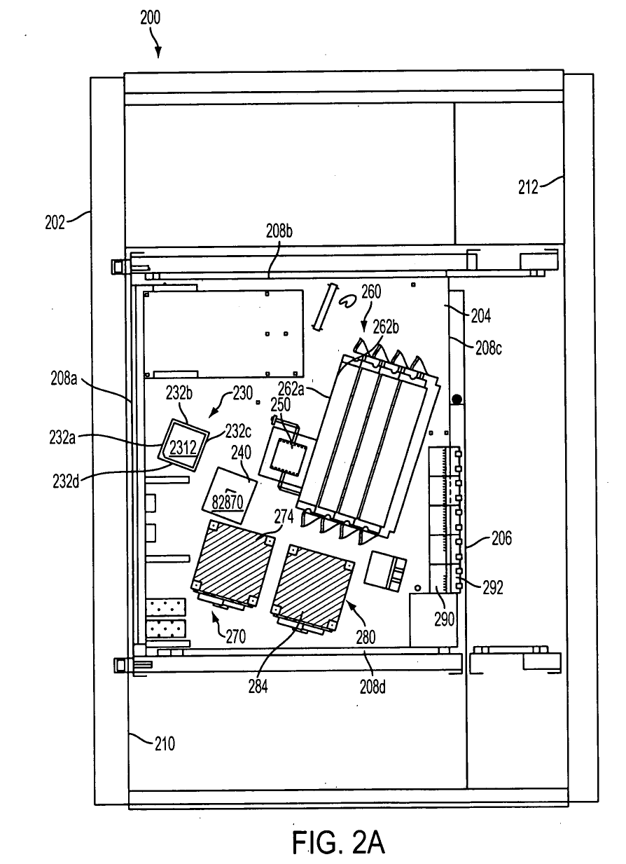

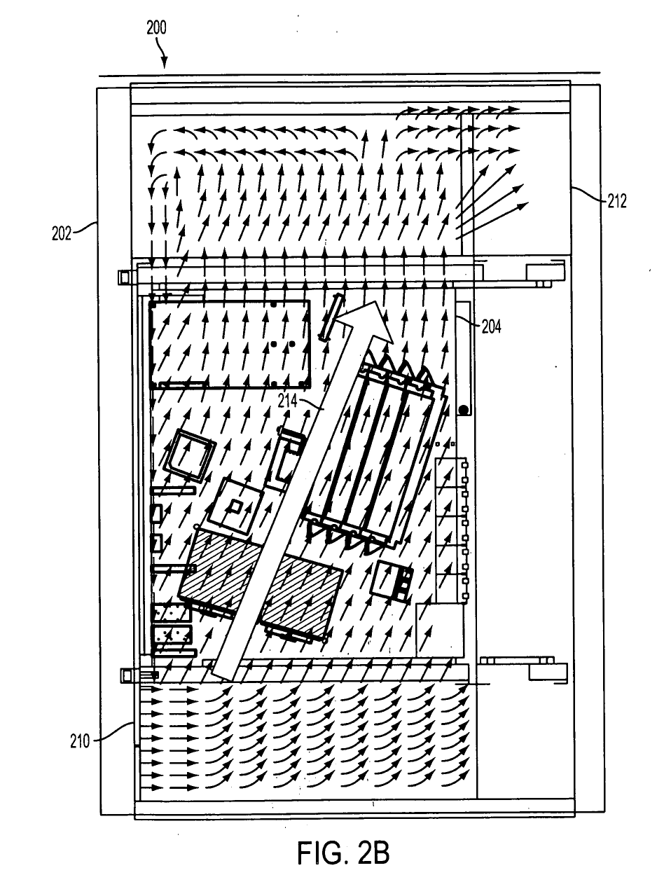

Referring to FIGS. 2A and 2B, one embodiment of a computer or electronic system 200 may include a chassis 202 and one or more circuit boards 204 including one or more skewed components 230, 240, 250, 260, 270, 280. The circuit boards 204 may be positioned and coupled to the backplane 206 such that the circuit boards 204 are orthogonal relative to the sides of the chassis 102. The skewed components 230, 240, 250, 260, 270, 280 may thus be skewed relative to the circuit board 204 such that components 230, 240, 250, 260, 270, 280 are aligned with a diagonal predominant air flow path 214 through the chassis 202 (FIG. 2B). As mentioned above, the predominant air flow path 214 through the chassis 202 corresponds to the path of least resistance from an air inlet 210 to an air outlet 212.

According to one example, a component 260, such as a memory module, may be aligned with the predominant air flow path 214 when the edges 262a, 262b (e.g., the longer edges) of the component 260 are generally parallel to the predominant air flow path 214. The skewed components 230, 240, 250, 260, 270, 280 may be aligned with the predominant air flow path 214, however, without having edges perfectly parallel to the predominant air flow path 214. Those skilled in the art will recognize that the orientation of the skewed components may diverge from the predominant air flow path 214 by a negligible amount that still allows back pressure to be reduced (as compared to an orthogonal orientation relative to the circuit board).

To provide the alignment, the components 230, 240, 250, 260, 270, 280 may be skewed at an angle relative to an edge 208a of the circuit board 204, which is within the range of the angle Θ (e.g., about 45°±20°) of the predominant air flow path 214 relative to the side of the chassis 202. Skewed components may be positioned and mounted to circuit boards with a skewed orientation using existing pick and place machines known to those skilled in the art. A pick and place machine may position and mount a component 230, such as a co-processor, for example, such that edges 232a-232d of the component 230 are obliquely angled (e.g., within the range of the angle Θ) relative to edges 208a-208d of the circuit board 204.

The skewed components 230, 240, 250, 260, 270, 280 may include, for example, co-processors, chipsets, graphics chips, central processing units (CPUs) and memory modules. Skewed components may also include heat sinks mounted on another skewed component. Heat sinks 274, 284 mounted on heat generating components 270, 280 (e.g., the CPU components) may be skewed such that the fins of the heat sinks 274, 284 are aligned with (e.g., generally parallel to) the predominant air flow path 214. Circuit boards in the chassis 202 may also include skewed components without any heat sinks.

Certain components may still be oriented orthogonally on the circuit board(s) 204. Edge connectors 290, for example, may be oriented orthogonally (i.e., perpendicular to the edges of the circuit board) so that the connectors 290 may interface with connectors 292 on the backplane 206. Also, components that provide negligible impedance to air flow (e.g., components with a low profile or outside of the predominant air flow path) may still be oriented orthogonally.

Although the illustrated embodiment shows skewed components 230, 240, 250, 260, 270, 280 on the circuit board(s) 204 coupled to the backplane 206, other circuit boards in the chassis 202 may also include skewed components in alignment with the predominant air flow path, as described above. Daughter or mezzanine cards (not shown), such as an Advanced Mezzanine Card (AMC), configured to be coupled to the circuit board(s) 204, for example, may include one or more skewed components, as described above. Those skilled in the art will recognize that various other configurations are within the scope of the present disclosure.

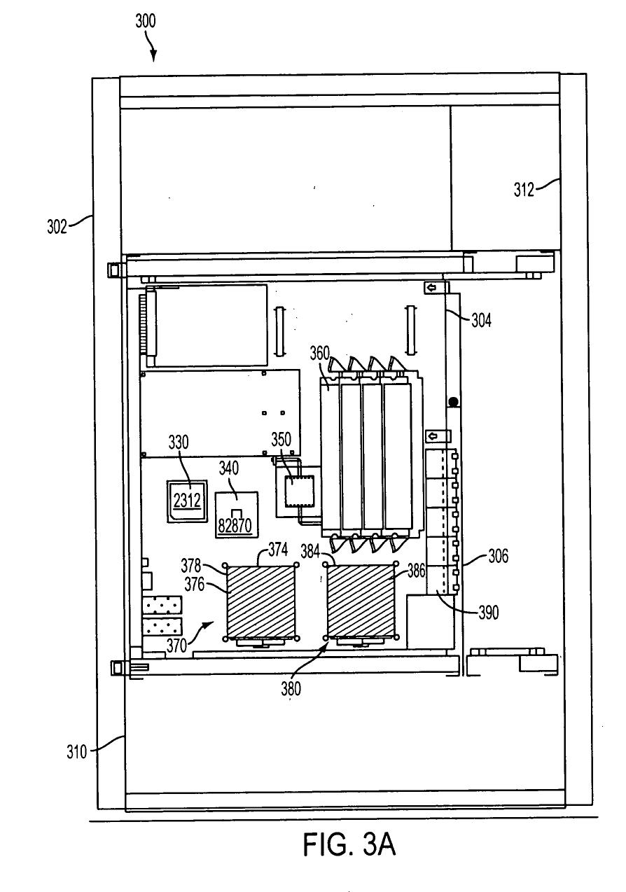

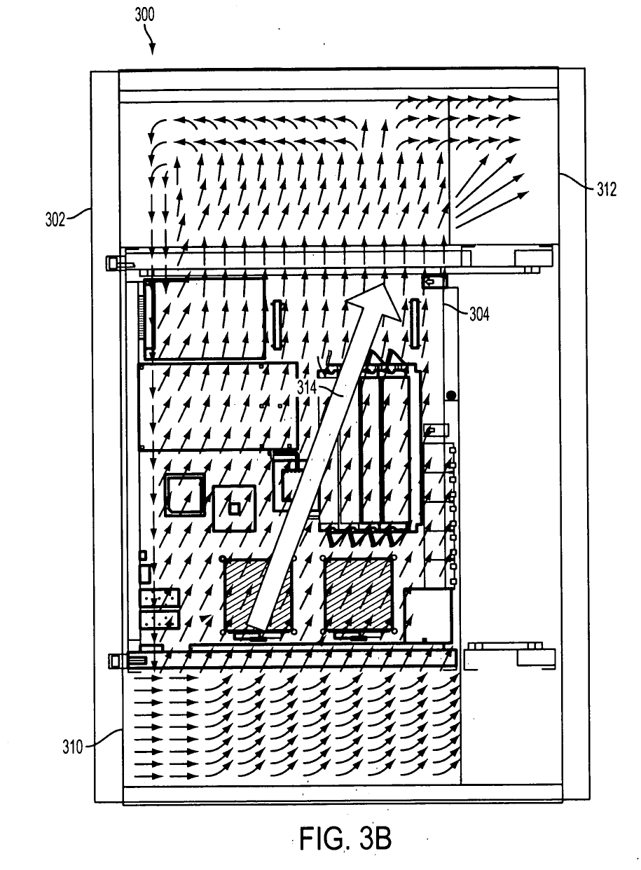

Referring to FIGS. 3A and 3B, another embodiment of a computer or electronic system 300 may include a chassis 302 and one or more circuit boards 304 including one or more heat sinks 374, 384 with angled fins 376, 386. The angled fins 376, 386 may be obliquely angled on the heat sinks 374, 384 such that the fins 376, 386 are aligned with a predominant air flow path 314 (FIG. 3B) through the chassis 302 when the circuit board 304 is mounted in the chassis 302, even though heat generating components 370, 380 may be orthogonally mounted. As mentioned above, the predominant air flow path 314 through the chassis 302 corresponds to the path of least resistance from an air inlet 310 to an air outlet 312. The fins 376, 386 of the heat sinks 374,384 may thus be angled to improve the heat sink profile for the air flow patterns within the chassis 302, thereby reducing airflow impedance and increasing thermal transfer.

The angled fins 376, 386 may be aligned with the predominant air flow path 314 when the fins 376, 386 are generally parallel to the predominant air flow path 314. The fins 376, 386 may be aligned with the predominant air flow path 314, however, without being perfectly parallel to the predominant air flow path 314. Those skilled in the art will recognize that the orientation of the fins may diverge from the predominant air flow path 314 by a negligible amount that still allows back pressure to be reduced (as compared to orthogonal fins).

The heat sinks 374, 384 may include a base that mounts to the heat generating components 370, 380 such that the base is generally orthogonal and parallel to the circuit board 304. The angled fins 376, 386 extend out of the base (e.g., perpendicular to the base) and into the flow path. To provide the alignment, the fins 376 form an oblique angle relative to an edge 378 of the heat sink 374, which is within the range of the angle Θ (e.g., about 45°±20°) of the predominant air flow path 314 relative to the side of the chassis 302. The dimensions and configuration of the heat sinks 374, 384 may otherwise be similar to existing heat sinks known to those skilled in the art (e.g., for use on CPU components).

Thus, the angled fins 376, 378 may be aligned with the predominant air flow path 314 even when the heat sink(s) 374, 384 are mounted and thermally coupled to heat generating components 370, 380 that are orthogonally oriented relative to the circuit board(s) 304. The heat sinks 374, 384 may thus improve the cooling capacity on existing circuit boards where heat generating components have already been placed orthogonally. The circuit board(s) 304 may also include other components 330, 340, 350, 360, 390 that are orthogonally positioned on the circuit board 304 (e.g., with edges of the components perpendicular to edges of the circuit board). The circuit board 304 may also include one or more skewed components as described above.

Although the heat sinks 374, 384 are shown with straight fins 376, 386, those skilled in the art will recognize that other heat sink designs may be used with fins that are not straight (e.g., curved or undulating). In such heat sinks, the non-straight fins (not shown) may be aligned such that longitudinal axes of the fins are generally parallel to the predominant air flow path through the chassis. Those skilled in the art will recognize that various other configurations are within the scope of the present disclosure.

As a result of the skewed components (see FIGS. 2A and 2B) and/or the heat sinks(s) with obliquely angled fins (see FIGS. 3A and 3B), backpressure in the chassis may be decreased and the cooling capacity within the chassis may be increased, as compared to an orthogonal orientation. The increased cooling capacity within a chassis may be illustrated using heat transfer relationships. The pressure drop within a chassis may be represented as follows:
ΔP=C*V² (Eq. 1)
where V=velocity of air and C=air property constants. The convective heat transfer coefficient may be represented as follows:
h_{c}=(C*V^{0.75})/L^{0.25} (Eq. 2)
where V=velocity of air, C=air property constants, and L=characteristic length. The energy analysis (due to convection) may be represented as follows:
Q=1/(h_{c}*A) (Eq. 3)
where Q=cooling capacity (Power, Watts) and A=area of heat transfer surface.

As the pressure drop (ΔP) decreases within a chassis, with all other parameters held constant, the air velocity (V) will increase. The increased air velocity will increase the convective heat transfer coefficient (h_{c}), thus increasing the cooling capacity (Q) within the chassis. According to simulations, the back pressure may be decreased by about 10% as a result of the impingement angle of the air flow moving to a generally parallel flow over the skewed components. A reduction in back pressure by about 10% may increase the velocity of air flow by about 30% with an accompanying increase in convective heat transfer of about 20%.

The reduced back pressure and increased air flow thus allows higher power, higher performance components, smaller fans, and/or lower profile heat sinks. The reduced back pressure may also reduce the acoustic noise generated by turbulence as the air traverses through the chassis, thereby minimizing a need for active and passive noise cancellation.

In one embodiment, the chassis (e.g., chassis 102, 202, 302) may include a plurality of circuit boards (e.g., circuit boards 104, 204, 304) coupled to a common backplane in a parallel arrangement and spaced apart in the chassis to allow for the height of the components on the circuit boards. In one example, fourteen (14) or sixteen (16) circuit boards may be coupled to a backplane with a pitch in the range of about 6 HP (about 30.48 mm or 1.2 in.) to allow a maximum component height of the circuit boards in a range of about 21.33 mm. In this example, the circuit boards may have a size in a range of about 8U×280 mm. Some of the circuit boards may also include mezzanine cards including additional components and coupled generally parallel to the circuit board (e.g., carrier boards) and within the spacing between the circuit boards. One or more of the plurality of circuit boards in such a chassis may include the skewed component(s) and/or the heat sink(s) with angled fins.

The computer systems 100, 200, 300 may be an advanced telecommunications computing architecture (Advanced TCA or ATCA) chassis complying with or compatible with, at least in part, PCI Industrial Computer Manufacturers Group (PICMG), Advanced Telecommunications Computing Architecture (ATCA) Base Specification, PICMG 3.0 Rev. 2.0, published Mar. 18, 2005, and/or later versions of the specification (“the ATCA specification”). According to such an embodiment, the chassis 102, 202, 302 may be ATCA chassis complying with or compatible with, at least in part, the ATCA Specification and the circuit boards 104, 204, 304 may be ATCA blades complying with or compatible with, at least in part, the ATCA Specification.

Various other embodiments consistent with the present disclosure may include a chassis and/or circuit boards complying with and/or compatible with technical specifications other than and/or in addition to the ATCA Specification. The alignment of components with a predominant air flow path, for example, may also be applied to circuit boards in other types of chassis including, but not limited to, VME chassis and CompactPCI chassis. The computer systems 100, 200, 300 may also be implemented in other chassis including a plurality of parallel circuit boards (e.g., blades) coupled to a backplane, such as the type available under the name IBM BladeCenter®. The scope of the present disclosure should not, therefore, be construed as being limited to any particular computer system or form factor.

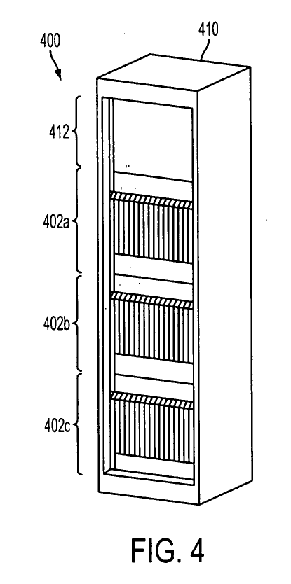

Referring to FIG. 4, a system 400 may include a frame or cabinet 410 that accommodates and electrically couples a plurality of chassis 402a, 402b, 402c. According to one example, a cabinet 410 may be provided by a telecommunications equipment manufacturer (TEM) to house telecommunications equipment. One or more of the chassis 402a, 402b, 402c may include at least one circuit board including components configured and/or oriented to improve air flow consistent with any embodiment described herein. The cabinet 410 may include, for example, a power supply for providing power to each of the individual chassis 402a, 402b, 402c and other equipment 412 (e.g., alarms, power distribution units, etc.) disposed in the cabinet 410. Additionally, as mentioned above, the cabinet 410 may electrically couple one or more of the chassis 402a, 402b, 402c to at least one other chassis.

According to an alternative embodiment, rather than being disposed in a common cabinet, a system consistent with the present disclosure may include a plurality of chassis that may be individually hardwired to one another without a cabinet. One or more of the plurality of chassis may include at least one circuit board consistent with any embodiment described herein. Additionally, each of the plurality of chassis may be powered by an individual power supply and/or may be separately powered by a common power supply. Such a system may, therefore, provide a greater freedom in the physical arrangement and interrelation of the plurality of chassis.

Consistent with one embodiment, an apparatus may include a computer system chassis including an air inlet and an air outlet located cater-cornered from the air inlet such that the chassis is configured to allow an air flow along a diagonal predominant air flow path through the computer system chassis. At least one circuit board is configured to be positioned in the computer system chassis. The circuit board may include a plurality of components coupled to the circuit board. At least one of the components may be aligned with the diagonal predominant air flow path when the circuit board is positioned in the computer system.

Consistent with another embodiment, an apparatus may include a circuit board including four circuit board edges and a plurality of components coupled to the circuit board. The components include a plurality of skewed components, and each of the skewed components has component edges oriented obliquely relative to the circuit board edges such that the component edges are aligned with a predominant air flow path through a chassis configured to receive the circuit board. The components include at least one heat sink including fins oriented obliquely relative to the circuit board edges such that the fins are aligned with the predominant air flow path through the chassis configured to receive the circuit board.

Consistent with a further embodiment, a method may include: determining a predominant air flow path through a chassis configured to house at least one circuit board; and mounting a plurality of components to at least one circuit board with a skewed orientation such that edges of the components are aligned with the predominant air flow path through the chassis when the circuit board is contained therein.

Consistent with yet another embodiment, a system may include a cabinet comprising a plurality of chassis with at least one of the chassis being an Advanced Telecommunications Computing Architecture (ATCA) chassis. The chassis include an air inlet and an air outlet located cater-cornered from the air inlet such that the chassis is configured to allow an air flow along a diagonal predominant air flow path through the chassis. At least one circuit board is disposed in the chassis and includes a plurality of components coupled to the circuit board. At least one of the components is aligned with the diagonal predominant air flow path when the circuit board is positioned in the computer system.

Various features, aspects, and embodiments have been described herein. The features, aspects, and embodiments are susceptible to combination with one another as well as to variation and modification, as will be understood by those having skill in the art. The present disclosure should, therefore, be considered to encompass such combinations, variations, and modifications.

The terms and expressions which have been employed herein are used as terms of description and not of limitation, and there is no intention, in the use of such terms and expressions, of excluding any equivalents of the features shown and described (or portions thereof), and it is recognized that various modifications are possible within the scope of the claims. Other modifications, variations, and alternatives are also possible. Accordingly, the claims are intended to cover all such equivalents.

What is claimed is:

1. An apparatus comprising:
a computer system chassis including an air inlet and an air outlet, said air outlet being located cater-cornered from said air inlet such that said chassis is configured to allow an air flow along a diagonal predominant air flow path through said computer system chassis; and
at least one circuit board configured to be positioned in said computer system chassis, said at least one circuit board including a plurality of components coupled to said circuit board, at least one of said components being aligned with said diagonal predominant air flow path when said circuit board is positioned in said computer system.

2. The apparatus of claim 1 wherein said chassis is an Advanced Telecommunications Computing Architecture (ATCA) chassis, and wherein said circuit board is an ATCA blade.

3. The apparatus of claim 1 wherein said air inlet is located in a front bottom region of said chassis and said air outlet is located in a rear top region of said chassis.

4. The apparatus of claim 1 wherein said at least one of said components is coupled to said circuit board such that edges of said at least one of said components are obliquely oriented relative to edges of said circuit board, and wherein at least some of said edges of said at least one of said components are aligned with said diagonal predominant air flow path.

5. The apparatus of claim 1 wherein said components include a plurality of skewed components coupled to said circuit board such that edges of said skewed components are obliquely oriented relative to edges of said circuit board.

6. The apparatus of claim 5 wherein said skewed components include memory modules and processors.

7. The apparatus of claim 5 wherein said skewed components are skewed within a range of angles of about 45°±20°.

8. The apparatus of claim 1 wherein said at least one of said components includes at least one heat sink including fins aligned with said diagonal predominant air flow path.

9. The apparatus of claim 8 wherein said at least one heat sink is skewed relative to said circuit board.

10. The apparatus of claim 8 wherein said fins are angled obliquely relative to an edge of said heat sink.

11. The apparatus of claim 10 wherein said heat sink is thermally coupled to a heat generating component, said heat generating component being oriented orthogonally relative to said circuit board.

12. The apparatus of claim 8 wherein said fins are angled obliquely relative to an edge of said heat sink within a range of angles of about 45°±20°.

13. An apparatus comprising:
a circuit board including four circuit board edges; and
a plurality of components coupled to said circuit board, wherein said components include a plurality of skewed components, each of said skewed components having component edges oriented obliquely relative to said circuit board edges such that said component edges are aligned with a predominant air flow path through a chassis configured to receive said circuit board, wherein said skewed components further include at least one heat sink coupled to at least one of said components, said heat sink including fins oriented obliquely relative to said circuit board edges such that said fins are aligned with the predominant air flow path through the chassis configured to receive said circuit board.

14. The apparatus of claim 13 wherein said skewed components are skewed within a range of angles of about 45°±20°.

15. The apparatus of claim 13 wherein said circuit board is an Advanced Telecommunications Computing Architecture (ATCA) blade.

16. The apparatus of claim 13 wherein said skewed components include memory modules and processors.

17. A method comprising:
determining a predominant air flow path through a chassis configured to house at least one circuit board; and
mounting a plurality of components to at least one circuit board with a skewed orientation such that edges of said components are aligned with said predominant air flow path through said chassis when said circuit board is contained therein.

18. The method of claim 17 wherein mounting said plurality of components includes mounting at least one heat generating component to said at least one circuit board and mounting at least one heat sink to said heat generating component, said heat sink including fins aligned with said predominant air flow path through said chassis.

19. The method of claim 17 wherein said components are mounted such that said edges of said components are angled relative to edges of said circuit board within a range of angles of about 45°±20°.

20. The method of claim 17 wherein said chassis is an Advanced Telecommunications Computing Architecture (ATCA) chassis, and wherein said circuit board is an ATCA blade.

21. The method of claim 17 wherein said components mounted with said skewed orientation include memory modules, processors, and heat sinks.

22. A system comprising:
a cabinet comprising a plurality of chassis, at least one of said plurality of chassis being an Advanced Telecommunications Computing Architecture (ATCA) chassis, said ATCA chassis including an air inlet and an air outlet located cater-cornered from said air inlet such that said ATCA chassis is configured to allow an air flow along a diagonal predominant air flow path through said ATCA chassis; and
at least one circuit board disposed in said ATCA chassis, said at least one circuit board including a plurality of components coupled to said circuit board, at least one of said components being aligned with said diagonal predominant air flow path when said circuit board is positioned in said ATCA chassis.

23. The system of claim 22 wherein said components include a plurality of skewed components coupled to said circuit board such that edges of said components are obliquely oriented relative to edges of said circuit board and aligned with said diagonal predominant air flow path.

24. The system of claim 22 wherein said at least one of said components includes at least one heat sink including fins aligned with said diagonal predominant air flow path.

25. The system of claim 24 wherein said fins are angled obliquely relative to an edge of said heat sink within a range of angles of about 45°±20°.
